(19) United States
(12) Patent Application Publication
(10) Pub. No.: US 2026/0157079 A1
(43) Pub. Date: Jun. 4, 2026

(54) DISPLAY DEVICE AND DISPLAY PANEL

(71) Applicant: LG DISPLAY CO., LTD., Seoul (KR)

(72) Inventors: Seonhee LEE, Paju-si (KR); Wonyeol CHOI, Paju-si (KR)

(73) Assignee: LG DISPLAY CO., LTD., Seoul (KR)

(21) Appl. No.: 19/283,027

(22) Filed: Jul. 28, 2025

(30) Foreign Application Priority Data
Oct. 21, 2024 (KR) 10-2024-0143558

(51) Int. Cl. H10K 59/80; H10K 59/12; H10K 59/88

(52) U.S. Cl. CPC H10K 59/80522; H10K 59/1201; H10K 59/80521; H10K 59/873; H10K 59/88

(57) ABSTRACT

A display panel can include a display area having a light emitting element including a first electrode, an emission layer, and a second electrode, and a bezel area located outside of the display area. Also, the bezel area includes an auxiliary electrode and a contact area, and the second electrode is in electrical contact with the auxiliary electrode at the contact area, and the contact area corresponds to at least one hole in the emission layer.

### CROSS REFERENCE TO RELATED APPLICATION

This application claims priority to Korean Patent Application No. 10-2024-0143558, filed on Oct. 21, 2024, in the Republic of Korea, the entirety of which is hereby incorporated by reference into the present application for all purposes as if fully set forth herein.

### BACKGROUND

### Technical Field

The present disclosure relates to electronic devices, and more specifically, to a display device and a display panel that have the structure of a narrow bezel.

### Discussion of the Related Art

As display devices for displaying images using digital data, liquid crystal display (LCD) devices using liquid crystals, organic light emitting display devices using organic light emitting diodes (OLED), and the like are widely used.

Among these display devices, organic light emitting display devices using organic light emitting diodes, which are self-emission elements, have the characteristics of fast response speed, high contrast ratio, high luminous efficiency, high luminance, wide viewing angle, and the like. For example, light emitting diodes can be implemented with an inorganic or organic material.

Organic light emitting display devices can include an organic light emitting diode disposed in each of a plurality of subpixels SP disposed in a display panel. Image production by light emitted from the organic light emitting diodes can be performed by controlling current flowing through, or voltage applied to, the organic light emitting diodes, and in this way, as luminance from each subpixel is controlled, the organic light emitting display devices can display images.

In an example where an organic light emitting display device is configured to have a top-emission structure, to enable light emitted from emission layers to travel upward, a cathode electrode can include a transparent metal or a metal with a translucent property. Further, to acquire light transmittance of the cathode electrode capable of allowing a sufficient amount of light to be transmitted, the cathode electrode can have a very small thickness (e.g., a very thin, transparent cathode electrode).

According to these considerations, the cathode electrode can include ITO or an alloy of silver (Ag) and magnesium (Mg) having a sufficiently thin thickness.

However, a decrease in the thickness of the cathode electrode can increase the electrical resistance of the cathode electrode. Due to such increases resistance, a voltage drop (e.g., an IR drop) can occur in a driving voltage supplied to an organic light emitting display panel, and a phenomenon can occur in which the luminescence of an image displayed through the display panel becomes uneven.

In particular, such voltage drop can be aggravated as the size of the display panel increases. Thus, a need exists for a display panel having a configuration that can reduce a voltage drop and minimize power consumption while also achieving a narrow bezel design.

### SUMMARY OF THE DISCLOSURE

To address these issues, inventors of the present disclosure have invented a display device and a display panel that include a structure capable of reducing a voltage drop phenomenon in the display panel.

One or more aspects of the present disclosure can provide a display device and a display panel that include a structure in which an auxiliary electrode electrically contacting a cathode electrode is disposed in a bezel area, and are capable of being driven at low power by minimizing a voltage drop phenomenon in the display panel.

One or more aspects of the present disclosure can provide a display device and a display panel that include a structure in which a cathode electrode and an auxiliary electrode electrically contact each other at a location overlapping with an emission layer in a bezel area, and are capable of ensuring a deposition margin in the bezel area and implementing a lightweight narrow bezel.

According to one or more example embodiments of the present disclosure, a display panel can be provided that includes a display area in which light emitted from a light emitting element including a first electrode, an emission layer, and a second electrode is presented, and a bezel area located outside of the display area and including an auxiliary electrode electrically contacting the second electrode at a contact area overlapping with the emission layer.

According to one or more example embodiments of the present disclosure, a display device can be provided that includes a display panel including a display area in which light emitted from a light emitting element including a first electrode, an emission layer, and a second electrode is presented, and a bezel area located outside of the display area and including an auxiliary electrode electrically contacting the second electrode at a contact area overlapping with the emission layer, and a driving circuit configured to drive the display panel.

According to one or more aspects of the present disclosure, a display device and a display panel can provide an effect or advantage of reducing a voltage drop phenomenon in the display panel.

According to one or more aspects of the present disclosure, a display device and a display panel can provide an effect or advantage of minimizing a voltage drop phenomenon in the display panel and being driven at low power by disposing an auxiliary electrode electrically contacting a cathode electrode in a bezel area.

According to one or more aspects of the present disclosure, a display device and a display panel can provide an effect or advantage of ensuring a deposition margin in a bezel area and implementing a lightweight narrow bezel based on a structure in which a cathode electrode and an auxiliary electrode electrically contact each other at a location overlapping with an emission layer in the bezel area.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example display device according to aspects of the disclosure;

FIG. 2 is an example perspective view of the display device according to aspects of the disclosure;

FIG. 3 illustrates an example equivalent circuit of at least one subpixel included in the display device according to aspects of the disclosure;

FIG. 4 is an example cross-sectional view of the display device according to aspects of the disclosure;

FIG. 5 illustrates an example configuration in which a first electrode and a second electrode electrically contact each other in a bezel area in the display device according to aspects of the disclosure;

FIGS. 6 to 9 illustrate example processes of manufacturing the display panel according to aspects of the disclosure;

FIG. 10 illustrates an example design margin in a configuration in which a first electrode and a second electrode electrically contact each other in a bezel area overlapping with an emission layer in the display panel according to aspects of the disclosure;

FIG. 11 illustrates an example design margin in a configuration in which a first electrode and a second electrode electrically contact each other in a contact area overlapping with an emission layer in a second bezel area in the display panel according to aspects of the disclosure;

FIG. 12 is an example plan view of a first contact area formed in a first bezel area in the display panel according to aspects of the disclosure;

FIG. 13 is an example plan view of a second contact area formed in a second bezel area in the display panel according to aspects of the disclosure;

FIGS. 14A-14D illustrate example shapes of contact areas at which a first electrode and a second electrode electrically contact each other at a location overlapping with an emission layer in a bezel area in the display panel according to aspects of the disclosure;

FIG. 15 illustrates an example first contact area formed in a first bezel area in the display panel according to aspects of the disclosure; and

FIG. 16 illustrates example contact areas differently formed in a first bezel area and a second bezel area in the display panel according to aspects of the disclosure.

### DETAILED DESCRIPTION OF THE EMBODIMENTS

Hereinafter, some embodiments of the present disclosure will be described in detail with reference to exemplary drawings. Reference will now be made in detail to example embodiments of the present disclosure, examples or aspects of which can be illustrated in the accompanying drawings. In the following description, the structures, implementations, methods, and operations described herein are not limited to the specific examples, aspects, and embodiments set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Further, in the following description of examples or embodiments of the present invention, detailed descriptions of well-known functions and components incorporated herein will be omitted when it is determined that the description can make the subject matter in some embodiments of the present invention rather unclear. Where the terms “comprise,” “have,” “include,” “contain,” “constitute,” “compose, “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa. The features of various embodiments of the present disclosure can be partially or entirely coupled to or combined with each other and can be interlocked and operated in technically various ways, and the embodiments can be carried out independently of or in association with each other.

Hereinafter, various embodiments of the present disclosure will be described in detail with reference to the accompanying drawings.

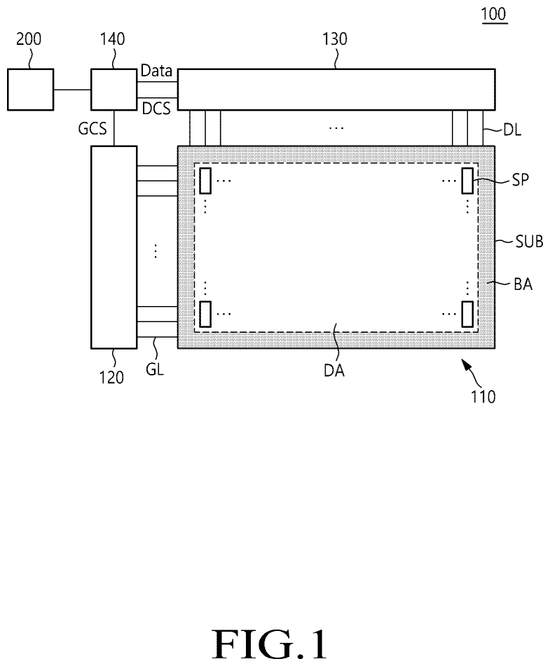

FIG. 1 illustrates an example display device according to aspects of the present disclosure.

Referring to FIG. 1, in one or more example embodiments, a display device 100 can include a display panel 110 and at least one driving circuit for driving the display panel 110.

The display panel 110 can include a display area DA in which an image can be displayed and a bezel area BA in which an image is not displayed. The bezel area BA can also be referred to as a non-display area, or a non-active area.

The display panel 110 can include a plurality of subpixels SP for image displaying. For example, the plurality of subpixels SP can be disposed in the display area DA. In one or more aspects, at least one subpixel SP can be disposed in the bezel area BA. The at least one subpixel SP disposed in the bezel area BA can be referred to as a dummy subpixel.

The display panel 110 can include a plurality of signal lines for driving the plurality of subpixels SP. For example, the plurality of signal lines can include a plurality of data lines DL and a plurality of gate lines GL. The signal lines can further include other signal lines, in addition to the plurality of data lines DL and the plurality of gate lines GL, according to structures of the subpixels SP. For example, such signal lines can include driving voltage lines, reference voltage lines, and the like.

The plurality of data lines DL and the plurality of gate lines GL can intersect each other. Each of the plurality of data lines DL can extend in a first direction. Each of the plurality of gate lines GL can extend in a second direction different from the first direction. For example, the first direction can be a column or vertical direction, and the second direction can be a row or horizontal direction. Herein, the column direction and the row direction may not represent absolute directions, but can represent relative directions. For example, the column direction can be the vertical direction and the row direction can be the horizontal direction. In another example, the column direction can be the horizontal direction and the row direction can be the vertical direction.

The at least one driving circuit can include a data driving circuit 130 for driving a plurality of data lines DL and a gate driving circuit 120 for driving a plurality of gate lines GL. The at least one driving circuit can further include a timing controller 140 for controlling the data driving circuit 130 and the gate driving circuit 120.

The data driving circuit 130 can be a circuit for driving the plurality of data lines DL and can output data signals (which can be referred to as data voltages) corresponding to image signals to the plurality of data lines DL. The gate driving circuit 120 can be a circuit for driving the plurality of gate lines GL and can generate gate signals and supply the generated gate signals to the plurality of gate lines GL. The gate signals can include at least one scan signal and at least one emission signal.

The timing controller 140 can start to scan pixels according to respective timings set in each frame, and can control data driving at timings set for scanning corresponding one or more of the pixels. The timing controller 140 can convert image data received from an external device or system (e.g., a host system 200) to a data signal form readable by the data driving circuit 130, and then supply image data DATA resulting from the converting to the data driving circuit 130.

The timing controller 140 can receive display driving control signals along with the image data from the external host system 200. In one or more aspects, the display driving control signals can include a vertical sync signal, a horizontal sync signal, an input data enable signal, a clock signal, and the like. However, aspects of the present disclosure are not limited thereto.

The timing controller 140 can generate data driving control signals DCS and gate driving control signals GCS based on the display driving control signals received from the host system 200. The timing controller 140 can control the driving operation and driving timing of the data driving circuit 130 by supplying the data driving control signals DCS to the data driving circuit 130. The timing controller 140 can control the driving operation and driving timing of the gate driving circuit 120 by supplying the gate driving control signals GCS to the gate driving circuit 120.

The data driving circuit 130 can include one or more source driving integrated circuits SDIC. Each source driver integrated circuit SDIC can include a shift register, a latch circuit, a digital to analog converter, an output buffer, and the like. However, aspects of the present disclosure are not limited thereto. In one or more aspects, each source driver integrated circuit SDIC can further include an analog-to-digital converter (ADC).

In one or more aspects, each source driver integrated circuit SDIC can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The gate driving circuit 120 can supply a gate signal of a turn-on level voltage, a gate signal of a turn-off level voltage, or a gate signal with a turn-on level and a turn-off level according to the control of the timing controller 140. The gate driving circuit 120 can sequentially drive a plurality of gate lines GL by sequentially supplying gate signals of the turn-on level voltage to the plurality of gate lines GL.

The gate driving circuit 120 can include one or more gate driving integrated circuits GDIC.

In one or more aspects, the gate driving circuit 120 can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. However, aspects of the present disclosure are not limited thereto. In one or more aspects, the gate driving circuit 120 can be disposed in the bezel area BA of the display panel 110 by a gate-in-panel (GIP) technique. The gate driving circuit 120 can be disposed on a substrate, or connected to the substrate. In an example where the gate driving circuit 120 is implemented by the gate-in-panel (GIP) technique, the gate driving circuit 120 can be disposed in the bezel area BA of the substrate. For example, when the GIP-type gate driving circuit 120 is used, the GIP-type gate driving circuit 120 can be disposed in, and/or electrically connected to, but not limited to, one side or edge (e.g., a left portion or a right portion) of the display panel 110. In one or more aspects, the gate driving circuit 120 can be connected to the substrate when the gate driving circuit 120 is implemented by the chip-on-glass (COG) technique, the chip-on-film (COF) technique, or the like.

In one or more aspects, at least one of the data driving circuit 130 and the gate driving circuit 120 can be disposed in the display area DA. For example, at least one of the data driving circuit 130 and the gate driving circuit 120 can be disposed not to overlap with subpixels SP, or be disposed to overlap with one or more, or all of the subpixels SP.

The data driving circuit 130 can be located in, and/or electrically connected to, but not limited to, only one side or edge (e.g., an upper portion or a lower portion) of the display panel 110. In one or more aspects, the data driving circuit 130 can be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 120 can be located in, and/or electrically connected to, but not limited to, one side or edge (e.g., a left portion or a right portion) of the display panel 110. In one or more aspects, the gate driving circuit 120 can be disposed in, and/or electrically connected to, but not limited to, two sides or edges (e.g., a left portion and a right portion) of the display panel 110 or at least two of four sides or edges (e.g., the left portion, the right portion, an upper portion, and a lower portion) of the display panel 110 according to driving schemes, panel design schemes, or the like.

The timing controller 140 can be implemented in a separate component from the data driving circuit 130, or integrated with the data driving circuit 130, so that the timing controller 140 and the data driving circuit 130 can be implemented in a single integrated circuit. The timing controller 140 can be a controller used in the typical display technology or a control apparatus/device capable of additionally performing other control functionalities in addition to the typical function of the timing controller. In one or more embodiments, the timing controller 140 can be one or more other control circuits different from the timing controller, or a circuit or component in the control apparatus/device. The timing controller 140 can be implemented with various circuits or electronic components such as an integrated circuit (IC), a field programmable gate array (FPGA), an application specific integrated circuit (ASIC), a processor, and/or the like.

The timing controller 140 can be mounted on a printed circuit board, a flexible printed circuit, or the like, and can be electrically connected to the data driving circuit 130 and the gate driving circuit 120 through the printed circuit board, the flexible printed circuit, and/or the like. The timing controller 140 can transmit signals to, and receive signals from, the data driving circuit 130 via one or more predetermined interfaces. In one or more aspects, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, the display device 100 can be a liquid crystal display device, a self-emission display device in which light is emitted from the display panel 110 itself, or the like. In an example where the display device 100 is a self-emission display device, each of the plurality of subpixels SP included in the display device 100 can include a light emitting element such as an organic light emitting diode, an inorganic light emitting diode, a quantum dot light emitting diode, a micro light emitting diode, a mini light emitting diode, or the like. In one or more aspects, the display device 100 can be an organic light emitting display device in which the light emitting element is implemented using an organic light emitting diode (OLED).

In one or more aspects, the display device 100 can be an inorganic light emitting display device in which the light emitting element is implemented using an inorganic material-based light emitting diode. In one or more aspects, the display device 100 can be a quantum dot display device in which the light emitting element is implemented using quantum dots, which are self-emission semiconductor crystals.

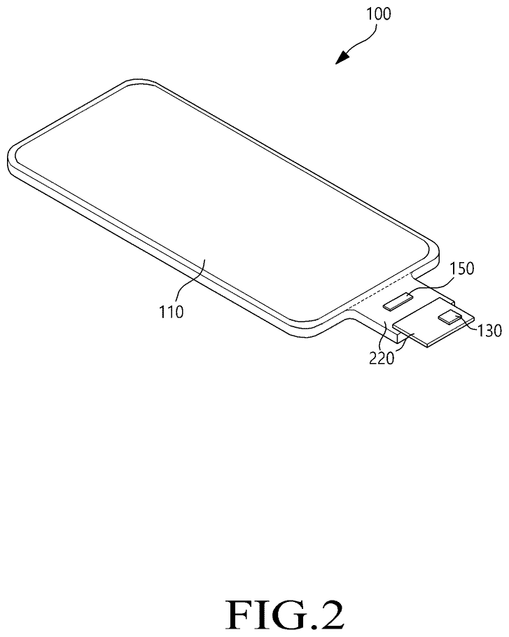

FIG. 2 is an example perspective view of the display device 100 according to aspects of the present disclosure.

Referring to FIG. 2, in one or more example embodiments, the display device 100 can be applied to portable electronic devices such as a mobile phone, a smart phone, a tablet personal computer (PC), a mobile communication terminal, an electronic notebook, an electronic book, a portable multimedia player (PMP), a navigation device, an ultra-mobile PC (UMPC), and the like.

Further, the display device 100 can be applied to a television, a laptop, a monitor, a billboard, a wearable device such as a smart watch, a watch phone, etc., and the like.

The display device 100 can include the display panel 110, the data driving circuit 130, a touch circuit 150, and a printed circuit board 220.

The display panel 110 can have a rectangular shape with a short side in a first direction and a long side in a second direction intersecting the first direction. Corners where the short side in the first direction and the long side in the second direction meet can be rounded to have a predetermined curvature or be formed at a right angle (e.g., a rectangular shape with rounded corners). The shape of the display panel 110 in a plan view is not limited to the rectangular or square shape. For example, the display panel 110 can be formed in a polygonal, circular, or oval shape in the plan view. The display panel 110 can be formed flat, but is not limited thereto. For example, the display panel 110 can include curved portions formed at left and right ends and having a constant curvature or a varying curvature. In one or more aspects, the display panel 110 can be formed flexibly to allow at least a portion of the display panel 110 to be bent, curved, folded, or rolled.

The display panel 110 can include the display area DA in which an image can be displayed and a bezel area BA outside of, or surrounding, the display area DA. The display area DA can include subpixels capable of emitting light for producing an image.

A printed circuit board 220 can be disposed on one side of the display panel 110, and the touch circuit 150 and the data driving circuit 130 can be mounted on the printed circuit board 220. The gate driving circuit can be disposed in the bezel area BA of the display panel 110 in the GIP type.

In one or more aspects, locations at which the data driving circuit 130 and the touch circuit 150 are disposed can be interchanged, and the data driving circuit 130 and the touch circuit 150 can be mounted together on a single printed circuit board 220 or can be mounted separately on different printed circuit boards. However, aspects of the present disclosure are not limited thereto.

In one or more aspects, the touch circuit 150 can be implemented in an integrated circuit (IC) and can be attached to the display panel 110 by the chip-on-glass (COG) technique, the chip-on-film (COF) technique, or an ultrasonic bonding technique, but aspects of the present disclosure are not limited thereto.

The printed circuit board 220 can be attached to one side of the display panel 110. According to this implementation, the printed circuit board 220 can be electrically connected to the display panel 110 and the touch circuit 150.

The touch circuit 150 can be implemented as an integrated circuit (IC) and be attached to the printed circuit board 220. The touch circuit 150 can be electrically connected to touch electrodes of a touch screen panel located in (or on or under) a display panel 110. The touch circuit 150 can apply a touch driving signal to a plurality of touch electrodes, detect a change in capacitance formed on at least one or more of the plurality of touch electrodes, and determine whether a touch object (e.g., a finger, a pen, and the like) is in contact with, or in close proximity to, a touch sensitive portion or surface of the display panel 110. For example, the touch by the touch object can be a direct contact of a user's body such as a finger or a pen with the surface of a cover glass placed on the touch electrode. For example, the close proximity by the touch object can be a situation where a user's body such as a finger or a pen is hovered away by a certain distance from the surface of the cover glass.

The display panel 110 and the display driving circuit 130 can receive digital video data, timing signals, and driving voltages through the printed circuit board 220. In one or more aspects, the printed circuit board 220 can be in the form of a flexible film such as a flexible printed circuit board or a chip-on-film, but aspects of the present disclosure are not limited thereto.

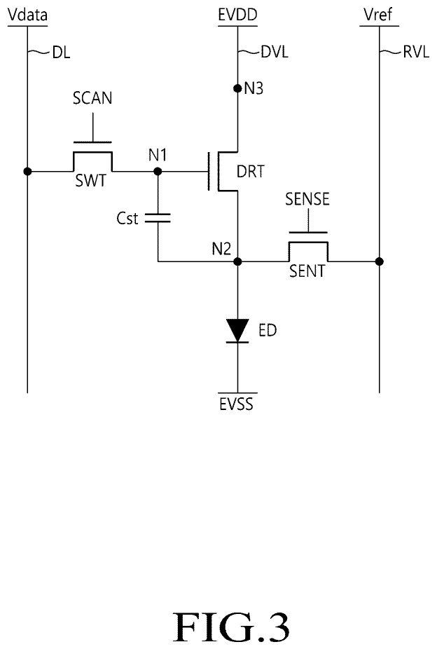

FIG. 3 illustrates an example equivalent circuit of at least one subpixel included in the display device 100 according to aspects of the present disclosure.

Referring to FIG. 3, in one or more example embodiments, each, or at least one, of a plurality of subpixels SP included in the touch display device 100 can include one or more transistors and a capacitor, and include an organic light emitting diode OLED as a light emitting element.

For example, a subpixel SP can include a driving transistor DRT, a switching transistor SWT, a sensing transistor SENT, a storage capacitor Cst, and a light emitting element ED such as an organic light emitting diode (OLED), an inorganic light emitting diode (LED), a quantum dot (QD) light emitting element, a micro light emitting diode, a mini light emitting diode, or the like.

The driving transistor DRT has a first node N1, a second node N2, and a third node N3. The first node N1 of the driving transistor DRT can be a gate node to which a data voltage Vdata delivered through a data line DL from the data driving circuit 130 is applied when the switching transistor SWT is turned on. The second node N2 of the driving transistor DRT can be electrically connected to the anode electrode of the light emitting element ED and be the source node or drain node of the driving transistor DRT. The third node N3 of the driving transistor DRT can be electrically connected to a high voltage line DVL (which can be referred to as a subpixel driving voltage line DVL) to which a high voltage EVDD (which can be referred to as a subpixel driving voltage EVDD is applied, and can be the drain node or the source node.

In these configurations, during a display driving period, a subpixel driving voltage EVDD needed to produce an image can be supplied through the high voltage line DVL. For example, the subpixel driving voltage EVDD can be about 27 V.

The switching transistor SWT can be electrically connected between the first node N1 and a data line DL, and be driven by a scan signal SCAN delivered through a gate line GL connected to the gate node of the switching transistor SWT. When the switching transistor SWT is turned on, the switching transistor SWT can control the operation of the driving transistor DRT by transferring a data voltage Vdata delivered through the data line DL to the gate node of the driving transistor DRT.

The sensing transistor SENT can be electrically connected between the second node N2 of the driving transistor DRT and a reference voltage line RVL, and be driven by a sense signal SENSE delivered through a gate line GL connected to the gate node of the sensing transistor SENT. When the sensing transistor SENT is turned on, a sensing reference voltage Vref delivered through the reference voltage line RVL can be transferred to the second node N2 of the driving transistor DRT.

For example, voltages in the first and second nodes of the driving transistor DRT can be controlled by controlling the switching transistor SWT and the sensing transistor SENT, and thereby, current for driving the organic light emitting diode OLED can be provided to the organic light emitting diode OLED.

The gate nodes of the switching transistor SWT and the sensing transistor SENT can be connected to a signal gate line GL or to different signal lines. FIG. 3 illustrates an example structure in which the scan transistor SWT and the sensing transistor SENT are connected to different gate lines GL, and in this structure, the scan transistor SWT and the sensing transistor SENT can be independently controlled by a scan signal SCAN and a sense signal SENSE delivered through the different gate lines GL.

In another example structure where the scan transistor SWT and the sensing transistor SENT are connected to one gate line GL, the scan transistor SWT and the sensing transistor SENT can be controlled concurrently or together by a scan signal SCAN or sense signal SENSE delivered through the one gate line GL, and thereby, an aperture ratio of a corresponding subpixel SP can be improved.

In one or more aspects, one or more of the transistors disposed in the subpixel SP can be n-type transistors or p-type transistors. For example, FIG. 3 illustrates that the transistors (e.g., DRT, SWT, and SENT) are n-type transistors.

The storage Capacitor Cst is electrically connected between the first node N1 and the second node N2 of the driving transistor DRT, and can remain a data voltage during one frame or a period of one frame.

The storage capacitor Cst can be connected between the first node N1 and the third node N3 of the driving transistor DRT according to a type of the driving transistor DRT. The anode electrode of the light emitting element ED can be electrically connected to the second node N2 of the driving transistor DRT, and a low voltage EVSS (e.g., which can be referred to as a base voltage EVSS) can be applied to the cathode electrode of the light emitting element ED.

For example, the base voltage EVSS can be a ground voltage or a voltage higher or lower than the ground voltage. The base voltage EVSS can be variable according to driving conditions. For example, a base voltage EVSS at a time of display driving and a base voltage EVSS at a time of sensing driving can be set to different values.

It should be understood that the subpixel structure with three transistors (3T) and one capacitor (1C) shown in FIG. 3 is merely one example of possible subpixel structures for convenience of discussion, and example embodiments of the present disclosure can be implemented in various structures. For example, the subpixel can further include at least one transistor and/or at least one capacitor. In one or more aspects, a plurality of subpixels can have the same structure, or at least one of the plurality of subpixels can have a structure different from the remaining one or more subpixels.

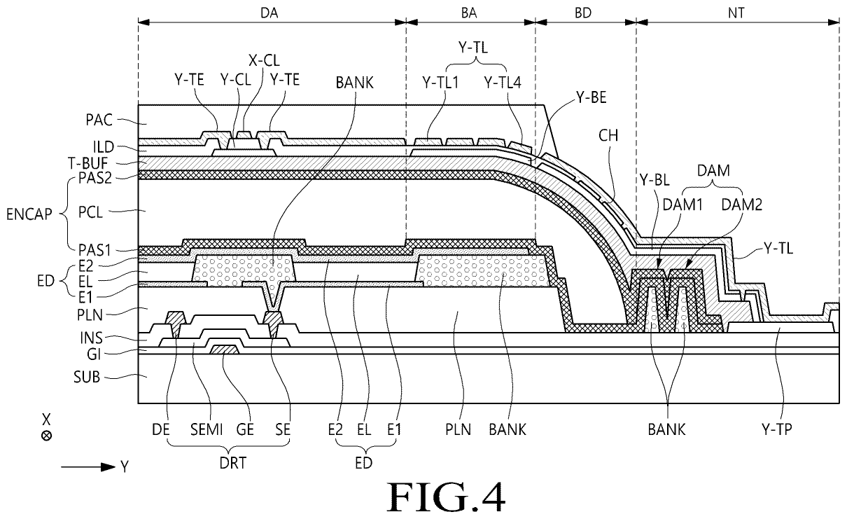

FIG. 4 is an example cross-sectional view of the display device 100 according to aspects of the present disclosure.

In one or more example embodiments, in the display device 100, at least one driving transistor DRT can be disposed on a substrate SUB in at least one subpixel SP located in the display area DA. Although FIG. 4 illustrates only one driving transistor DRT, but the switching transistor SWT, the sensing transistor SENT, and/or the storage capacitor Cst included in the subpixel of FIG. 3 can also be included in the stack-up configuration of FIG. 4.

Referring to FIG. 4, in the display device 100, the driving transistor DRT formed in the display area DA can include a gate electrode GE, a source electrode SE or a drain electrode DE, a semiconductor layer SEMI, and the like.

The gate electrode GE and the semiconductor layer SEMI can overlap with each other with a gate insulating layer GI interposed therebetween. The source electrode SE can be disposed on an insulating layer INS and contact one side of the semiconductor layer SEMI, and the drain electrode DE can be disposed on the insulating layer INS and contact the other side of the semiconductor layer SEMI.

The light emitting element ED can include a first electrode E1 (e.g., which can be an anode electrode), an emission layer EL disposed on the first electrode E1, and a second electrode E2 (e.g., which can be a cathode electrode) disposed on the emission layer EL.

The first electrode E1 can be electrically connected to the source electrode SE of the driving transistor DRT exposed through a contact hole of a planarization layer PLN.

The emission layer EL can be disposed on the first electrode E1 in a light emitting area defined by a bank BANK. The emission layer EL can include a stack of one or more hole-related layers, an element intermediate layer EL, and one or more electron-related layers, which can be stacked in this order or in a reverse order on the first electrode E1. The second electrode E2 can be disposed to face the first electrode E1 with the emission layer EL interposed therebetween. In one or more aspects, the one or more hole-related layers can be a hole transport layer, a hole injection layer, an electron blocking layer, and/or a p-type charge generation layer, but aspects of the present disclosure are not limited thereto. In one or more aspects, the one or more electron-related layers can be an electron transport layer, an electron injection layer, a hole blocking layer, or an n-type charge generation layer, but aspects of the present disclosure are not limited thereto.

An encapsulation layer ENCAP can block external moisture or oxygen from penetrating into the light emitting element ED that is vulnerable to external moisture or oxygen. The encapsulation layer ENCAP can be in the form of a single layer, or in the form of a stack of a plurality of layers (e.g., PAS1, PCL, PAS2).

For example, when the encapsulation layer ENCAP includes a plurality of stacked layers (e.g., PAS1, PCL, PAS2), the encapsulation layer ENCAP can include one or more inorganic encapsulation layers (e.g., PAS1 and PAS2) and one or more organic encapsulation layers PCL. For example, the encapsulation layer ENCAP can have a stack of a first inorganic encapsulation layer PAS1, an organic encapsulation layer PCL, and a second inorganic encapsulation layer PAS2, which are stacked in this order, but aspects of the present disclosure are not limited thereto.

The organic encapsulation layer PCL can further include at least one organic encapsulation layer or at least one inorganic encapsulation layer, but aspects of the present disclosure are not limited thereto.

Among these encapsulation layers, the first inorganic encapsulation layer PAS1 can be located closest to the light emitting element ED, and, for example, be disposed on the substrate SUB on which the second electrode E2, which is the cathode electrode, is disposed. The first inorganic encapsulating layer PAS1 can include, for example, an inorganic insulating material capable of being deposited at low temperature, such as silicon nitride (SiNx), silicon oxide (SiOx), silicon oxynitride (SiON), aluminum oxide (Al2O3), or the like, but aspects of the present disclosure are not limited thereto. As the first inorganic encapsulating layer PAS1 is deposited in the low temperature atmosphere, the first inorganic encapsulating layer PAS1 can prevent or reduce the emission layer EL including an organic material vulnerable to a high temperature atmosphere from being damaged during the deposition process.

The organic encapsulating layer PCL can be disposed with an area smaller than the first inorganic encapsulating layer PAS1, and, for example, the organic encapsulating layer PCL can be disposed to expose both ends of the first inorganic encapsulating layer PAS1. The organic encapsulation layer PCL can serve as a buffer to relieve stress between layers disposed on or under the organic encapsulation layer PCL due to the bending of the touch-enabled display device 100, and also serve to improve planarization performance. The organic encapsulation layer PCL can include, for example, an organic insulating material, such as an acrylic resin, an epoxy resin, a polyimide, polyethylene, silicon oxycarbon (SiOC), or the like, but aspects of the present disclosure are not limited thereto.

When the organic encapsulation layer PCL is formed by an inkjet process, one or more dams DAM can be disposed in a dam area corresponding to a boundary area between the non-display area (or bezel area BA) and the display area DA or a portion of the non-display area.

For example, the dam area can be located between a pad area where a plurality of touch pads TP are disposed in the non-display area and the display area DA. The dam area can include a first dam DAM1 adjacent to the display area DA and a second dam DAM2 adjacent to the pad area.

One or more dams DAM disposed in the dam area can prevent or reduce the organic encapsulation layer PCL in the form of liquid from overflowing toward the non-display area and reaching the pad area while the organic encapsulation layer PCL is formed in the display area DA.

The first dam DAM1 or the second dam DAM2 can have a single layer or multi-layer structure. For example, the first dam DAM1 or the second dam DAM2 can be formed simultaneously with the same material as at least one of a bank BANK and a spacer. Thereby, the dam structure can be formed without additional mask processes and increased costs. For example, the spacer can be disposed on the bank BANK.

In one or more aspects, the first dam DAM1 or the second dam DAM2 can have a structure in which the first inorganic encapsulation layer PAS1 and the second inorganic encapsulation layer PAS2 are stacked on the bank BANK. The organic encapsulation layer PCL including an organic material can be located on the inner surface of the first dam DAM1 or can be located on at least a portion of at least one of the first dam DAM1 and the second dam DAM2. For example, the first inorganic encapsulation layer PAS1 and the second inorganic encapsulation layer PAS2 can contact each other in the dam area to seal an edge of the organic encapsulation layer PCL and prevent moisture penetration.

The second inorganic encapsulation layer PAS2 can be disposed on the substrate SUB on which the organic encapsulation layer PCL is disposed such that the second inorganic encapsulation layer PAS2 covers respective upper surfaces and side surfaces of the organic encapsulation layer PCL and the first inorganic encapsulation layer PAS1. The second inorganic encapsulation layer PAS2 can minimize or block external moisture or oxygen from penetrating into the first inorganic encapsulation layer PAS1 and the organic encapsulation layer PCL. The second inorganic encapsulation layer PAS2 can include, for example, an inorganic insulating material, such as silicon nitride (SiNx), silicon oxide (SiOx), silicon oxynitride (SiON), aluminum oxide (Al2O3), or the like, but aspects of the present disclosure are not limited thereto.

In one or more aspects, the display device 100 can include a touch sensing structure in which a plurality of X-touch electrode lines (which can be referred to as a plurality of X-touch electrode arrays each including a plurality of X-touch electrodes) and a plurality of Y-touch electrode lines (e.g., which can be referred to as a plurality of Y-touch electrode arrays each including a plurality of Y-touch electrodes) are disposed. Referring to FIG. 4, the plurality of X-touch electrode lines and the plurality of Y-touch electrode lines can be disposed on the encapsulation layer ENCAP.

The plurality of X-touch electrode lines can be disposed in a first direction, and the plurality of Y-touch electrode lines can be disposed in a second direction different from the first direction.

The first direction and the second direction can be relatively different directions. For example, the first direction can be an x-axis direction, and the second direction can be a y-axis direction. In another example, the first direction can be the y-axis direction, and the second direction can be the x-axis direction. The first direction and the second direction can be orthogonal to each other, but may not be orthogonal to each other.

Each of The plurality of X-touch electrode lines can include a plurality of X-touch electrodes X-TE electrically connected to each other, and each of the plurality of Y-touch electrode lines can include a plurality of Y-touch electrodes Y-TE electrically connected to each other.

The plurality of X-touch electrodes X-TE and the plurality of Y-touch electrodes Y-TE can be included in a plurality of touch electrodes TE disposed in the display panel 110. For example, the plurality of X-touch electrodes X-TE included in each of the plurality of X-touch electrode lines can be touch driving electrodes, and the plurality of Y-touch electrodes Y-TE included in each of the plurality of Y-touch electrode lines can be touch sensing electrodes. The plurality of X-touch electrode lines can correspond to touch driving electrode lines, and the plurality of Y-touch electrode lines can correspond to touch sensing electrode lines.

In one or more aspects, touch sensor metals for touch sensing can include a plurality of touch lines in addition to the plurality of X-touch electrode lines and the plurality of Y-touch electrode lines.

The plurality of touch lines can include one or more X-touch lines X-TL connected to the plurality of X-touch electrode lines, and one or more Y-touch lines Y-TL connected to the plurality of Y-touch electrode lines.

Each of the plurality of X-touch electrode lines can include a plurality of X-touch electrodes X-TE disposed in the same row (or column), and one or more X-touch electrode connection lines X-CL electrically interconnecting the plurality of X-touch electrodes X-TE. An X-touch electrode connection line X-CL for connecting two adjacent X-touch electrodes X-TE can be a metal integrated with the two adjacent X-touch electrodes X-TE, or can be a metal connected to the two adjacent X-touch electrodes X-TE through a contact hole.

Referring to FIG. 4, a touch buffer layer T-BUF can be disposed on the encapsulation layer ENCAP. The touch buffer layer T-BUF can be located between touch sensor metals including touch electrodes (e.g., X-TE, Y-TE) and touch electrode connection lines (e.g., X-CL, Y-CL) and the second electrode E2 of the light emitting element ED.

The touch buffer layer T-BUF can be designed such that a distance between the touch sensor metals and the second electrode E2 of the light emitting element ED maintains a predefined minimum distance (e.g., about 1 μm). According to this configuration, a parasitic capacitance formed between the touch sensor metals and the second electrode E2 of the light emitting element ED can be reduced or prevented, thereby preventing or reducing the deterioration of touch sensitivity due to the parasitic capacitance.

In one or more aspects, touch sensor metals including touch electrodes (e.g., X-TE, Y-TE) and touch electrode connection lines (e.g., X-CL, Y-CL) can be disposed on the encapsulation layer ENCAP without the touch buffer layer T-BUF.

The touch buffer layer T-BUF can block a chemical solution (e.g., a developer solution, etchant, or the like) used in the process of manufacturing the touch sensor metals disposed on the touch buffer layer T-BUF or moisture from the outside from penetrating into the emission layer EL including an organic material. Accordingly, the touch buffer layer T-BUF can prevent or reduce damage to the emission layer EL which is vulnerable to the chemical solution or moisture. For example, the touch buffer layer T-BUF can be disposed to cover the touch sensor metals, thereby preventing or reducing the touch sensor metals from being corroded by external moisture, and the like.

The touch buffer layer T-BUF can be formed at a low temperature (e.g., about 100° C.) or lower to prevent or reduce damage to the emission layer EL including an organic material vulnerable to high temperatures, and include an organic insulating material having a low dielectric constant. For example, the touch buffer layer T-BUF can include an acrylic series, an epoxy series, or a siloxane series material, but aspects of the present disclosure are not limited thereto. The touch buffer layer T-BUF having an organic insulating material and having planarization performance can prevent or reduce damage to the layers (e.g., PAS1, PCL, and PAS2) included in the encapsulation layer ENCAP and breakage of touch sensor metals disposed on the touch buffer layer T-BUF, due to bending of the display device 100. In one or more aspects, the touch buffer layer T-BUF may not be disposed on the encapsulation layer ENCAP. For example, the touch buffer layer T-BUF may be omitted.

In a touch sensing structure configured to sense a touch based on mutual capacitance, X-touch electrode lines X-TEL and Y-touch electrode lines Y-TEL can be disposed on the touch buffer layer T-BUF, and the X-touch electrode lines X-TEL and the Y-touch electrode lines Y-TEL can be arranged to intersect each other. In one or more aspects, the Y-touch electrode lines Y-TEL can include a plurality of Y-touch electrode connection lines Y-CL for electrically interconnecting a plurality of Y-touch electrodes Y-TE.

The plurality of Y-touch electrodes Y-TE and the plurality of Y-touch electrode connection lines Y-CL can be located in different layers with an interlayer dielectric layer ILD therebetween.

The plurality of Y-touch electrodes Y-TE can be spaced apart from each other at a constant interval along the y-axis direction. Each of the plurality of Y-touch electrodes Y-TE can be electrically connected to another adjacent Y-touch electrode Y-TE in the y-axis direction through a corresponding one of the Y-touch electrode connection lines Y-CL.

The Y-touch electrode connection lines Y-CL can be disposed on the touch buffer layer T-BUF. Each Y-touch electrode connection line Y-CL can be exposed through a touch contact hole of the interlayer dielectric layer ILD and be electrically connected to two adjacent Y-touch electrodes Y-TE in the y-axis direction.

The Y-touch electrode connection line Y-CL can be disposed to overlap with the bank BANK. According to this configuration, the aperture ratio of the display device 100 can be prevented from being lowered by the Y-touch electrode connection lines Y-CL.

In one or more aspects, the X-touch electrode lines X-TEL can include a plurality of X-touch electrode connection lines X-CL for electrically interconnecting a plurality of X-touch electrodes X-TE. The plurality of X-touch electrodes X-TE and the plurality of X-touch electrode connection lines X-CL can be located in different layers with the interlayer dielectric layer ILD therebetween.

The plurality of X-touch electrodes X-TE can be spaced apart from each other by a constant interval along the x-axis direction on the interlayer dielectric layer ILD. Each of the plurality of X-touch electrodes X-TE can be electrically connected to another adjacent X-touch electrode X-TE in the x-axis direction through a corresponding one of the X-touch electrode connection lines X-CL.

Each X-touch electrode connection line X-CL can be disposed on the same plane or layer as the X-touch electrodes X-TE and thereby, be electrically connected to two adjacent X-touch electrodes X-TE in the x-axis direction without a separate contact hole, or can be integrally formed with two adjacent X-touch electrodes X-TE in the x-axis direction.

The X-touch electrode connection line X-CL can be disposed to overlap with the bank BANK. According to this configuration, the aperture ratio of the display device 100 can be prevented from being lowered by the X-touch electrode connection lines X-CL.

Each Y-touch electrode line Y-TEL can be electrically connected to the touch circuit 150 through a corresponding Y-touch line Y-TL and a corresponding Y-touch pad Y-TP. Each X-touch electrode line X-TEL can be electrically connected to the touch circuit 150 through a corresponding X-touch line X-TL and a corresponding X-touch pad X-TP.

In one or more aspects, at least one pad cover electrode covering at least one X-touch pad X-TP and at least one Y-touch pad Y-TP can be further disposed.

A corresponding X-touch line X-TL and a corresponding X-touch pad X-TP connected to each X-touch electrode line X-TEL can be formed separately from each other, or the X-touch pad X-TP can be a portion resulting from the extending of X-touch line X-TL. A corresponding Y-touch line Y-TL and a corresponding Y-touch pad Y-TP connected to each Y-touch electrode line Y-TEL can be formed separately from each other, or the Y-touch pad Y-TP can be a portion resulting from the extending of Y-touch line Y-TL.

In an example where the X-touch pad X-TP is a portion resulting from the extending of the X-touch line X-TL, and the Y-touch pad Y-TP is a portion resulting from the extending of the Y-touch line Y-TL, the X-touch pad X-TP, the X-touch line X-TL, the Y-touch pad Y-TP, and the Y-touch line Y-TL can include a same first conductive material. In one or more aspects, the first conductive material can be in the form of a single layer or multi-layer using a metal having strong corrosion resistance and acid resistance and good conductivity, such as aluminum (Al), titanium (Ti), copper (Cu), molybdenum (Mo), or the like, but aspects of the present disclosure are not limited thereto.

For example, X-touch pads X-TP, X-touch lines X-TL, Y-touch pads Y-TP, and Y-touch lines Y-TL including the first conductive material can have a stack of three layers, for example, Ti/Al/Ti or Mo/Al/Mo, but aspects of the present disclosure are not limited thereto.

The pad cover electrode that can cover at least one X-touch pad X-TP and at least one Y-touch pad Y-TP can include a second conductive material that is the same material as X-touch and Y-touch electrodes (e.g., X-TE, Y-TE). The second conductive material can include a transparent conductive material such as ITO or IZO, which has strong corrosion resistance and acid resistance. For example, the pad cover electrode can be exposed by the touch buffer layer T-BUF. In this example, the pad cover electrode can be bonded to the touch circuit 150 or bonded to a circuit film on which the touch circuit 150 is mounted.

The touch buffer layer T-BUF can be formed to cover touch sensor metals. Thereby, the touch buffer layer T-BUF can prevent or reduce the touch sensor metals from being corroded by external moisture. For example, the touch buffer layer T-BUF can include an organic insulating material, or be formed in the form of a circular polarizing plate or a film including epoxy or acrylic material. In one or more aspects, the touch buffer layer T-BUF may not be disposed on the encapsulation layer ENCAP. For example, the touch buffer layer T-BUF may be omitted.

Referring to FIG. 4, a Y-touch line Y-TL can be electrically connected to a Y-touch electrode Y-TE through a touch line contact hole, or can be formed integrally with the Y-touch electrode Y-TE.

The Y-touch line Y-TL can extend to the non-display area. For example, the Y-touch line Y-TL can extend from the display area along upper and side surfaces of the encapsulation layer ENCAP and upper and side surfaces of the dam DAM, and reach a Y-touch pad Y-TP. Thus, the Y-touch line Y-TL can be electrically connected to the Y-touch pad Y-TP. Thereby, the Y-touch line Y-TL can be electrically connected to the touch circuit 150 through the Y-touch pad Y-TP.

The Y-touch line Y-TL can deliver a touch sensing signal from the Y-touch electrode Y-TE to the touch circuit 150, and/or deliver a touch driving signal from the touch circuit 150 to the Y-touch electrode Y-TE.

Referring to FIG. 4, a Y-touch bridge line Y-BL connected through a contact hole CH can be disposed under the Y-touch line Y-TL in a notch area NT and a bending area BD. The Y-touch line Y-TL and the Y-touch bridge line Y-BL can be electrically connected through one or more contact holes CH spaced apart by a certain interval. Thereby, the Y-touch line Y-TL and the Y-touch bridge line Y-BL can deliver a same touch driving signal or touch sensing signal.

Thus, in the configuration where the Y-touch line Y-TL and the Y-touch bridge line Y-BL are electrically connected, an electrical resistance caused during delivering a touch driving signal or a touch sensing signal can be reduced. Further, in the configuration where the Y-touch line Y-TL and the Y-touch bridge line Y-BL are connected through one or more contact holes CH, even when a short circuit occurs in the Y-touch line Y-TL or the Y-touch bridge line Y-BL in a portion of the Y-touch line Y-TL or the Y-touch bridge line Y-BL, a touch signal (e.g., a touch driving signal or a touch sensing signal) can be bypassed through a corresponding one of one or more contact holes CH, and therefore, the performance of the touch sensing can be maintained.

Referring to FIG. 4, the Y-touch line Y-TL and the Y-touch bridge line Y-BL can be insulated in an area except for one or more contact holes CH by an interlayer dielectric layer ILD disposed therebetween.

A plurality of Y-touch lines (e.g., Y-TL1, Y-TL2, Y-TL3, Y-TL4) can be disposed in the bezel area BA, and at least one Y-touch bridge electrode Y-BE integrally formed with, or connected to, the Y-touch lines (e.g., Y-TL1, Y-TL2, Y-TL3, Y-TL4) can be disposed under the Y-touch lines (e.g., Y-TL1, Y-TL2, Y-TL3, Y-TL4).

When the at least one Y-touch bridge electrode Y-BE is integrally formed with the Y-touch lines (e.g., Y-TL1, Y-TL2, Y-TL3, Y-TL4) (hereinafter, which can be referred to as an integrally-formed structure), the at least one Y-touch bridge electrode Y-BE can have a width equal to or wider than those of the Y-touch lines (e.g., Y-TL1, Y-TL2, Y-TL3, Y-TL4) to cover an area occupied by the Y-touch lines (e.g., Y-TL1, Y-TL2, Y-TL3, Y-TL4) located on the at least one Y-touch bridge electrode Y-BE.

In one or more aspects, the Y-touch bridge electrode Y-BE can be connected to a ground voltage to discharge noise charges flowing into the display panel 110, and be separated from the Y-touch bridge line Y-BL located in the bending area BD.

According to this configuration, noise charges coming into the display panel 110 can be easily discharged to the ground voltage GND by the Y-touch bridge electrode (e.g., Y-BE) having the integrally-formed structure to cover the area occupied by the Y-touch lines (e.g., Y-TL1, Y-TL2, Y-TL3, Y-TL4), and thereby, the display device 100 can provide advantages of improving the touch sensing performance and reducing defects caused by display driving.

Referring to FIG. 4, an X-touch line X-TL can be electrically connected to a X-touch electrode X-TE through a touch contact hole, or can be formed integrally with the X-touch electrode X-TE.

The X-touch line X-TL can extend to the non-display area. For example, the X-touch line X-TL can extend from the display area along upper and side surfaces of the encapsulation layer ENCAP and upper and side surfaces of the dam DAM, and reach a X-touch pad X-TP. Thus, the X-touch line X-TL can be electrically connected to the X-touch pad X-TP. Thereby, the X-touch line X-TL can be electrically connected to the touch circuit 150 through the X-touch pad X-TP.

The X-touch line X-TL can deliver a touch driving signal from the touch circuit 150 to the X-touch electrode X-TE, and/or deliver a touch sensing signal from the X-touch electrode X-TE to the touch circuit 150.

The arrangement of the X-touch line X-TL and the Y-touch line Y-TL can be variously changed according to design requirements of the display panel 110.

Referring to FIG. 4, a touch protection layer PAC can be disposed on the X-touch electrode X-TE and the Y-touch electrode Y-TE. The touch protection layer PAC can extend to a front or rear portion of the dam DAM and also be disposed on the X-touch line X-TL and the Y-touch line Y-TL.

It should be noted that the cross-sectional structure in FIG. 4 conceptually illustrates a stack-up configuration of the display device 100, and a respective position, thickness, or width of one or more patterns (e.g., one or more layers or one or more electrodes) can vary depending on a viewing direction or position, and a respective connection structure of one or more patterns can also vary. Further, in addition to the illustrated layers, one or more layers can be added, and/or some of the illustrated layers can be omitted or integrated. For example, a width of the bank BANK can be narrower than that in FIG. 4, and a height of the dam DAM can be lower or higher than that in FIG. 4.

In one or more aspects, the display device 100 can be a mobile terminal, such as a smart phone, a tablet, or the like, or a monitor, a television (TV), or the like. Such apparatuses can be configured in various types, sizes, and shapes. The display device 100 according to aspects of the present disclosure are not limited thereto, and can include various types, sizes, and shapes configured to display information or images. A display apparatus according to the aspects of the present disclosure can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

The display device 100 can determine the presence or location of a touch by detecting touch sensing signals from one or more touch electrodes TE based on a single sensing-enabled structure or a differential sensing-enabled structure.

For example, in an example where the display device 100 has a top-emission structure that emits light upwardly, the second electrode E2, which is the cathode electrode, can be implemented as an electrode with transparent characteristics or an electrode with semi-transparent characteristics to emit light emitted from the emission layer EL upwardly.

In this implementation, to acquire light transmittance of the cathode electrode capable of allowing a sufficient amount of light to be transmitted, the cathode electrode can have a very small thickness. For example, to acquire the second electrode E2t having a sufficiently thin thickness, the second electrode E2 can include ITO, an alloy of silver (Ag) and magnesium (Mg), or the like.

However, a decrease in the thickness of the second electrode E2 can increase the electrical resistance of the second electrode E2. Due to such increased resistance, a voltage drop (i.e., an IR drop) can occur in a portion (e.g., in particular, a central portion) of the display panel 110, and thereby, a phenomenon can occur in which the luminescence of an image displayed through the display panel becomes uneven (e.g., a dark spot or dull region). Such voltage drop can be aggravated as the size of the display panel increases. For example, when the second electrode E2 is formed to be very thin (e.g., to improve transparency and light extraction), its electrical resistance can increase, and the issue can be exasperated as the display panel is made to be very large (e.g., a large screen TV, etc.).

In one or more aspects, the display device 100 can include a structure in which the cathode electrode is electrically contacted to an auxiliary electrode in the bezel area, and thereby, can provide advantages of reducing the electrical resistance of the cathode electrode and minimizing the voltage drop phenomenon caused by the cathode electrode, which can help provide uniform luminance across the entire screen.

In particular, the display device 100 can include the structure in which the cathode electrode and the auxiliary electrode electrically contact each other at a location overlapping with the emission layer in the bezel area, and thereby, can provide advantages of ensuring a deposition margin of the bezel area BA and implementing a narrow bezel.

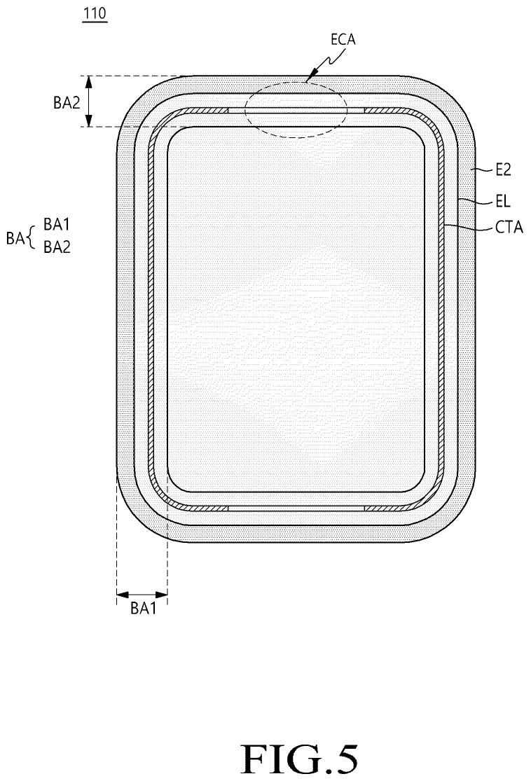

FIG. 5 illustrates an example configuration in which a first electrode and a second electrode electrically contact each other in a bezel area in the display device 100 according to aspects of the present disclosure.

Referring to FIG. 5, in one or more example embodiments, the display panel 110 included in the display device 100 can include the display area DA in which an image can be displayed and the bezel area BA in which an image is not displayed.

The bezel area BA can include a first bezel area BA1 located on the left and right of the display area DA and a second bezel area BA2 located on and underneath the display area DA, in a plan view.

In one or more aspects, an emission EL disposed on a first electrode E1, which is an anode electrode, can extend from the display area DA to a portion of the bezel area BA. To reduce a voltage drop in a second electrode E2, which is a cathode electrode, the display panel 110 can include a structure where the first electrode E1, which is the anode electrode, electrically contacts the second electrode E2.

Further, the second electrode E2 can be disposed on the emission layer EL such that the second electrode E2 covers the emission layer EL. For example, the second electrode E2 can extend from the display area DA to the bezel area BA and further extend to an outward area from, or an outer edge of, the emission layer EL. For example, emission layer EL and the second electrode E2 can be formed as sheets of material that extend across the display panel and the second electrode E2 can extend past the emission layer EL in the bezel area BA.

Referring to FIG. 5, to reduce a voltage drop by the second electrode E2, the display panel 110 can include a contact area CTA for electrically connecting the second electrode E2 and the first electrode E1 located under the second electrode E2 through a cut area at which a portion of the emission layer EL disposed in the bezel area BA is cut off. In other words, a portion of the emission layer EL can be cut away or burned away so that parts of the second electrode E2 can come into contact with the first electrode E1.

In this configuration, if the contact area CTA for electrically connecting the second electrode E2 and the first electrode E1 is formed in the display area DA, the resolution of the display area DA can be reduced.

To address this issue, in one or more aspects, the display panel 110 can be desired to have a structure where the contact area CTA for electrically connecting the second electrode E2 and the first electrode E1 is disposed in the bezel area BA, and the bezel area BA is designed to have a narrow width (e.g., which can be referred to as a narrow bezel).

The contact area CTA for electrically connecting the second electrode E2 and the first electrode E1 can be formed along an outer edge of the display area DA. The contact area CTA can be an area for electrically connecting the first electrode E1 and the second electrode E2, and a portion of the emission layer EL corresponding to the contact area CTA can be cut off or removed.

In one or more aspects, the contact area CTA for electrically connecting the first electrode E1 and the second electrode E2 can be formed continuously along the bezel area BA.

Referring to FIG. 5, in one or more aspects, a disconnection area ECA in which the first electrode E1 and the second electrode E2 do not electrically contact each other can be included in a portion of the contact area CTA.

Thus, the disconnection area ECA can be an area in which the first electrode E1 and the second electrode E2 do not electrically contact each other. For example, the disconnection area ECA can be an area where the first electrode E1 and the second electrode E2 are spaced apart from each other.

In one or more aspects, the disconnection area ECA can be an area where the emission layer EL is not cut off. In one or more aspects, the disconnection area ECA can be an area where the first electrode E1 is not formed or the second electrode E2 is not formed.

The disconnection area ECA can be an area where an influence (e.g., capacitance, magnetic field, electrical influence, or the like) can be exerted on an adjacent signal line by an electrical connection between the first electrode E1 and the second electrode E2, or be an area where the first electrode E1 or the second electrode E2 is not formed to efficiently arrange signal lines. For example, the disconnection area ECA can be an area for arranging wiring structures, and their electrical influence on the image quality of the display images can be prevented or minimized by keeping the first electrode E1 and the second electrode E2 spaced apart and disconnected from each other in this area.

In one or more aspects, the disconnection area ECA can be located in the second bezel area BA2.

In one or more aspects, the first electrode E1 of the first bezel area BA1 and the first electrode E1 of the second bezel area BA2 may or may not be connected to each other.

For example, a base voltage line to which a base voltage EVSS is applied can be connected to the second electrode E2. Therefore, the contact area CTA can be formed along an area where the base voltage line is disposed, and the disconnection area ECA can be formed in an area where the base voltage line is not disposed.

For example, in an example where the data driving circuit 103 is disposed in an upper portion of the display panel 110 and the base voltage line for delivering the base voltage runs along the left and right side surfaces of the display panel 110, the contact area CTA where the first electrode E1 and the second electrode E2 are electrically connected can be formed along the first bezel area BA1.

Therefore, the disconnection area ECA where the first electrode E1 and the second electrode E2 do not electrically contact each other can be formed along the second bezel area BA2 where the base voltage line is not formed.

In one or more aspects, a portion of the bezel area BA where the first electrode E1 is not formed can be the disconnection area ECA.

According to these configurations, when a portion of the emission layer EL in the bezel area BA is cut off and the first electrode E1 and the second electrode E2 electrically contact each other at a location overlapping with the emission layer EL, a narrow bezel can be implemented while minimizing a voltage drop.

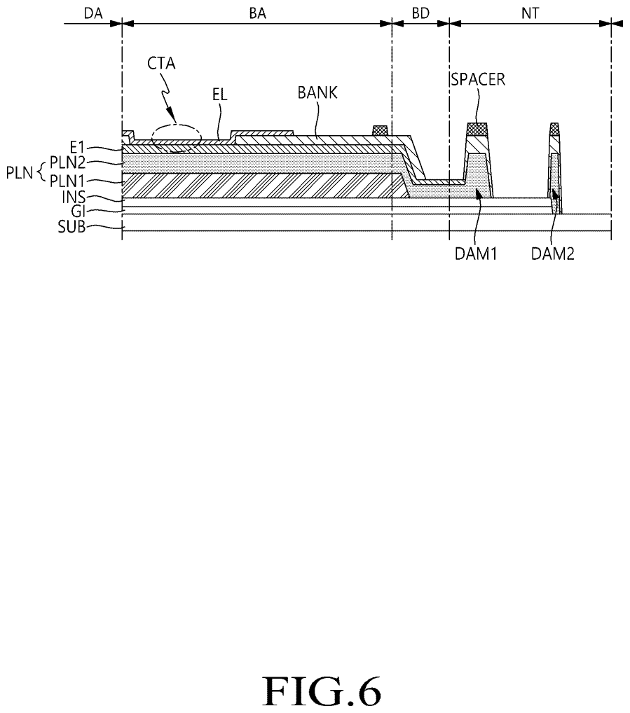

FIGS. 6 to 9 illustrate example processes of manufacturing the display panel 110 according to aspects of the present disclosure.

Referring to FIG. 6, in one or more example embodiments, in the display device 100, a substrate SUB, a gate insulating layer GI, and an insulating layer INS across a display area DA and a bezel area BA can be sequentially deposited.

FIG. 6 illustrates that a bending area BD where the display panel 110 is bent and a notch area NT are separately disposed outside of the bezel area BA, but both the bending area BD and the notch area NT can be considered to be included in the bezel area BA.

At least one driving transistor DRT for driving a corresponding subpixel SP can be disposed in the display area DA, but a driving transistor DRT may not be formed in the bezel area BA.

A planarization layer PLN can extend from the display area DA to the bezel area BA. In one or more aspects, the planarization layer PLN can have a structure in which a first planarization layer PLN1 and a second planarization layer PLN2 of different materials are stacked on top of each other.

One or more dams (e.g., DAM1, DAM2) can be formed in a dam area located in a portion of the bezel area BA.

For example, the dam area can include a first dam DAM1 adjacent to the display area DA and a second dam DAM2 outwardly adjacent to first dam DAM1. For example, the second dam DAM2 can be located outside of and surrounding the first dam DAM1.

The one or more dams (e.g., DAM1, DAM2) disposed in the dam area can prevent or reduce an organic encapsulation layer PCL in the form of liquid from overflowing toward the bezel area BA while the organic encapsulation layer PCL in the form of liquid is formed in the display area DA.

The first dam DAM1 or the second dam DAM2 can have a single layer or multi-layer structure. For example, the first dam DAM1 or the second dam DAM2 can include a bank BANK and a spacer SPACER. Thereby, the dam structure can be formed without additional mask processes and increased costs. The spacer SPACER can be disposed on the bank BANK.

An additional spacer can also be disposed on the bank BANK in an inward area from the dam area.

A light emitting element ED located in the display area DA can include a first electrode E1, which is an anode electrode, an emission layer EL disposed on the first electrode E1, and a second electrode E2, which is a cathode electrode, disposed on the emission layer EL.

In this configuration, the first electrode E1 can be disposed on the planarization layer PLN, and be formed not only in the display area DA but also in the bezel area BA. The first electrode E1 disposed in the bezel area BA can be electrically separated from the first electrode disposed in the display area DA.

The first electrode E1 can be formed only in a portion of the bezel area BA, or can extend from the bezel area BA to the dam area.

For example, in a first bezel area BA1 (e.g., the first bezel area BA1 of FIG. 5) where an electrical contact area between the first electrode E1 and the second electrode E2 is wide, the first electrode E1 can extend to the dam area, and in a second bezel area BA2 (e.g., the second bezel area BA2 of FIG. 5) where the first electrode E1 and the second electrode E2 do not contact each other or in the second bezel area BA2 having a narrow contact area, the first electrode E1 can be formed only in a boundary between the display area DA and the bezel area BA.

In one or more aspects, the emission layer EL located in the display area DA can be disposed to contact the first electrode E1 in a light emitting area formed in an open area of the bank BANK. Therefore, the light emitting area located in the display area DA can be an area in which light is emitted by the first electrode E1, the emission layer EL, and the second electrode E2 that are sequentially stacked, and correspond to the open area of the bank BANK.

Similarly, the emission layer EL located in the bezel area BA can also be exposed through an open area of the bank BANK. In one or more aspects, a contact area CTA of the bezel area BA can be located in the open area of the bank BANK and be formed with a width less than a width of the open area of the bank BANK. In one or more aspects, a plurality of contact areas CTA can be formed in the open area of the bank BANK.

The contact area CTA in the bezel area BA can be an area in which the emission layer EL is cut off or removed and thereby, the first electrode E1 and the second electrode E2 electrically contact each other.

Therefore, the contact area CTA of the bezel area BA can serve to reduce a voltage drop by enabling the first electrode E1 and the second electrode E2 to electrically contact each other.

In one or more aspects, the emission layer EL can include a stack of one or more hole-related layers, an element emission layer, and one or more electron-related layers, which are stacked in this order or in a reverse order on the first electrode E1.

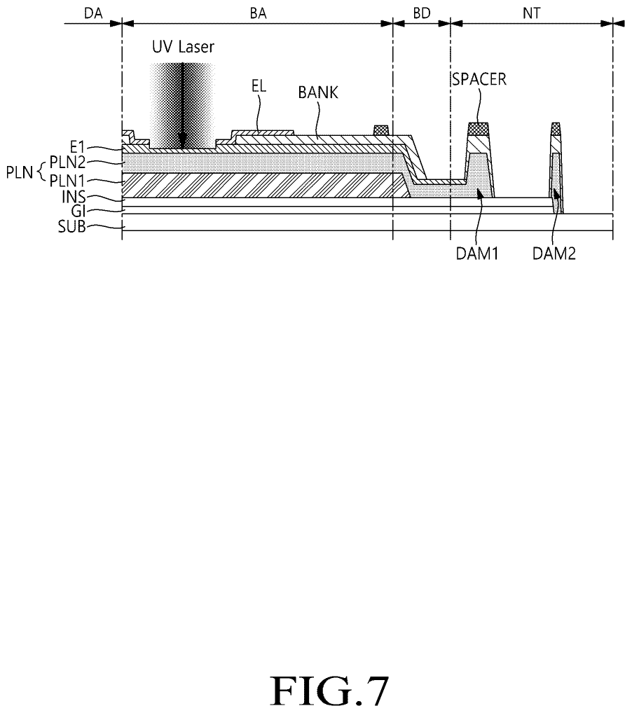

Referring to FIG. 7, at least a portion of the emission layer EL located in the contact area CTA of the bezel area BA can be removed using a high-frequency signal such as an ultraviolet laser.

In this process, the emission layer EL located in the contact area CTA of the bezel area BA can be removed or burned away using a high-frequency signal (e.g., a UV laser) or can be removed using various methods such as a photolithography process.

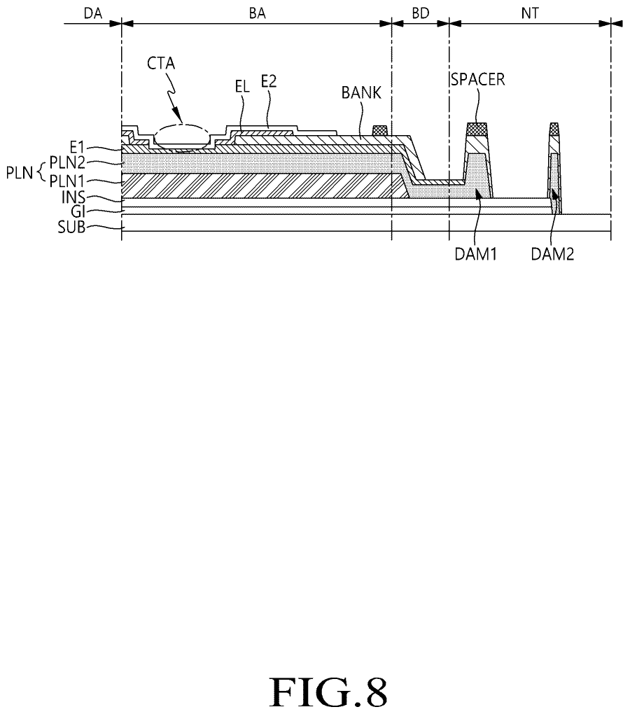

Referring to FIG. 8, a second electrode E2 can be formed to cover the emission layer EL after the emission layer EL has been cut off or removed by a high-frequency signal injected into the contact area CTA of the bezel area BA.

In this process, the second electrode E2 can electrically contact the first electrode E1 through the contact area CTA where the emission layer EL is opened.

According to these configurations, the electrical resistance of the second electrode E2 can be reduced, and the voltage drop phenomenon can be minimized.

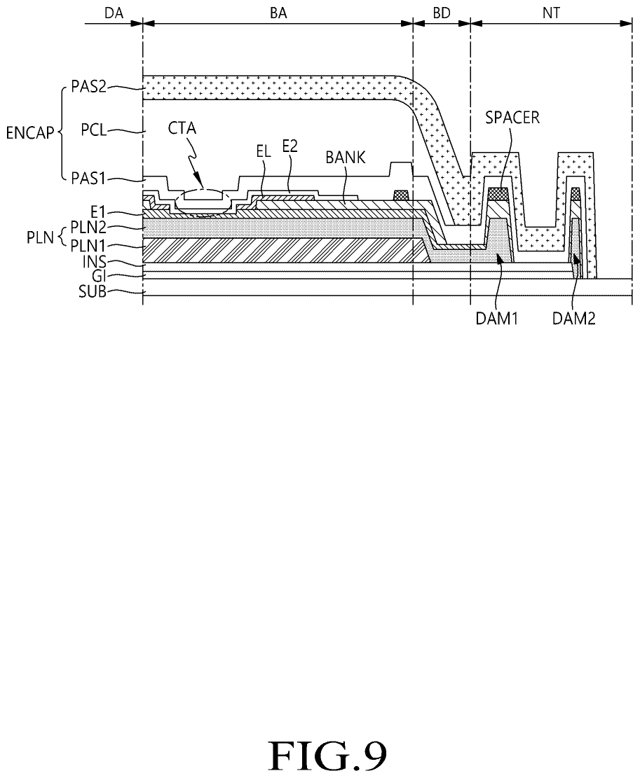

Referring to FIG. 9, to block external moisture or oxygen from penetrating into the light emitting element ED which is vulnerable to external moisture or oxygen, an encapsulation layer ENCAP can be formed on the light emitting element ED. The encapsulation layer ENCAP can be formed from the display area DA to a portion of the bezel area BA.

The encapsulation layer ENCAP can be in the form of a single layer, or in the form of a stack of a plurality of layers (e.g., PAS1, PCL, PAS2).

For example, when the encapsulation layer ENCAP includes a plurality of stacked layers (e.g., PAS1, PCL, PAS2), the encapsulation layer ENCAP can include one or more inorganic encapsulation layers (e.g., PAS1 and PAS2) and one or more organic encapsulation layers PCL. For example, the encapsulation layer ENCAP can have a stack of a first inorganic encapsulation layer PAS1, an organic encapsulation layer PCL, and a second inorganic encapsulation layer PAS2, which are stacked in this order.

The organic encapsulation layer PCL can be prevented or reduced from overflowing toward a pad area by one or more dams (e.g., DAM1, DAM2) formed in the dam area in the bezel area BA.

The first inorganic encapsulation layer PAS1 and the second inorganic encapsulation layer PAS2 can be sequentially stacked on a first dam DAM1 and a second dam DAM2.

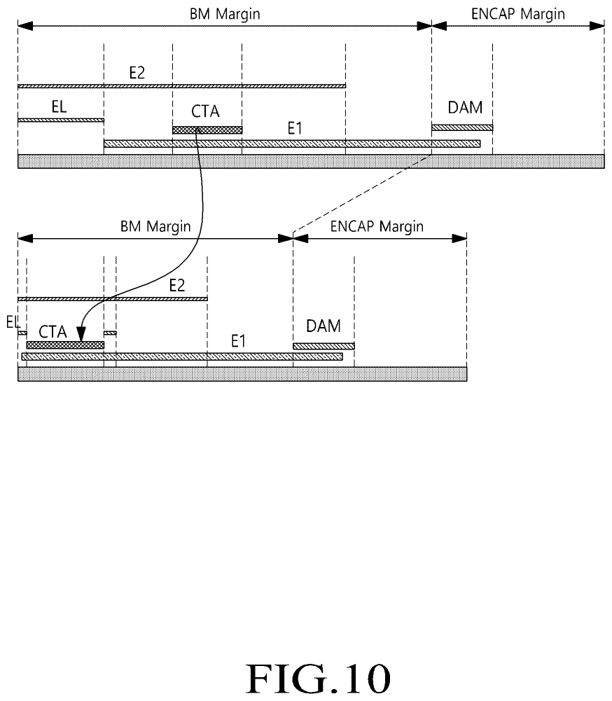

FIG. 10 illustrates an example design margin in a configuration in which a first electrode E1 and a second electrode E2 electrically contact each other in a bezel area BA overlapping with an emission layer EL in the display panel 110 according to aspects of the present disclosure.

Referring to FIG. 10, in one or more example embodiments, the display panel 110 can include a bezel area mask margin (BM Margin) for forming the bezel area BA outside of the display area DA and an encapsulation layer margin (ENCAP Margin) for preventing or reducing an encapsulation layer ENCAP from overflowing toward a pad area.

In this configuration, the smaller the bezel area mask margin (BM Margin), the easier a narrow bezel can be formed.

The first electrode E1 disposed in the bezel area BA can be electrically separated from a first electrode E1 disposed in the display area DA.

In the first bezel area BA1 where an electrical contact area between the first electrode E1 and the second electrode E2 is wide, the first electrode E1 can be formed up to a portion of the dam area.

In the bezel area BA, the emission layer EL can be located on the first electrode E1 such that the emission layer EL overlaps with a portion of the first electrode E1.

In one or more aspects, the display panel 110 can provide advantages of reducing the electrical resistance of the second electrode E2 and minimizing a voltage drop by including a structure where the second electrode E2 and the first electrode E1 electrically contact each other.

Further, the display panel 110 can provide advantages of having a narrow bezel by including a structure where a contact area CTA where the first electrode E1 and the second electrode E2 electrically contact each other is formed by the cutting of the emission layer EL, resulting in the bezel area mask margin (BM Margin) being sufficiently small. For example, by cutting through the emission layer EL to allow a contact area CTA between the first electrode E1 and the second electrode E2, this configuration can save space and the bezel can be made smaller, as shown in the example at the bottom of FIG. 10 (e.g., rather the example at the top of FIG. 10 where the first electrode E1 and the second electrode E2 contact each other farther away from an outermost edge of the emission layer EL).

In one or more aspects, in an example where the display panel 110 includes a structure where a contact area CTA where the first electrode E1 and the second electrode E2 electrically contact each other is formed in both the first bezel area BA1 and the second bezel area BA2, a first contact area formed in the first bezel area BA1 and a second contact area formed in the second bezel area BA2 can have different structures.

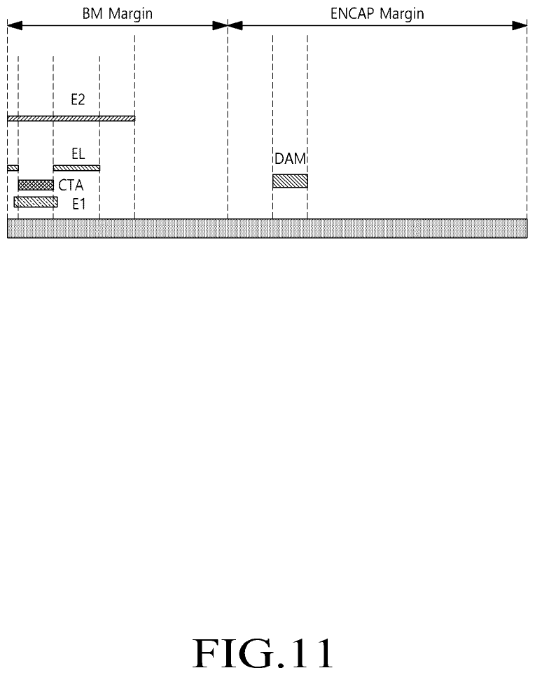

FIG. 11 illustrates an example design margin in a configuration in which a first electrode E1 and a second electrode E2 electrically contact each other in a contact area overlapping with an emission layer EL in the second bezel area BA2 in the display panel 110 according to aspects of the present disclosure.

Referring to FIG. 11, in one or more example embodiments, the display panel 110 can include a configuration where a first contact area formed in the first bezel area BA1 and a second contact area formed in the second bezel area BA2 have different structures.

For example, when the bezel area of FIG. 10 is the first bezel area BA1 located on the left and right of the display panel 110, the bezel area of FIG. 11 can be the second bezel area BA2 located on and underneath the display panel 110.

The second bezel area BA2 can include a bezel area mask margin (BM Margin) and an encapsulation layer margin (ENCAP Margin) for preventing or reducing an encapsulation layer ENCAP from overflowing toward a pad area.

The first electrode E1 formed in the second bezel area BA2 can be electrically separated from a first electrode E1 formed in the display area DA. In one or more example embodiments, a width of the first electrode E1 disposed in the second bezel area BA2 can be different from a width of the first electrode E1 disposed in the first bezel area BA1.

For example, the first electrode E1 disposed in the second bezel area BA2 can extend to a dam area, and the first electrode E1 disposed in the second bezel area BA2 may not extend to the dam area. For example, as shown in FIG. 11, the first electrode E1 can terminate within the bezel area mask margin (BM Margin) before reaching the dam area.

An emission layer EL can be disposed on the first electrode E1 disposed in the second bezel area BA2 such that the emission layer EL overlaps with a portion of the first electrode E1.

A portion of the emission layer EL can be cut off, and thereby, the second electrode E2 on the emission layer EL and the first electrode E1 under the emission layer EL can electrically contact each other. According to this configuration, the electrical resistance of the second electrode E2 can be reduced, and a voltage drop can be minimized.

In one or more aspects, in an example where the display panel 110 includes a structure where a contact area CTA where the first electrode E1 and the second electrode E2 electrically contact each other is formed in both the first bezel area BA1 and the second bezel area BA2, a first contact area formed in the first bezel area BA1 and a second contact area formed in the second bezel area BA2 can have different areas or sizes.

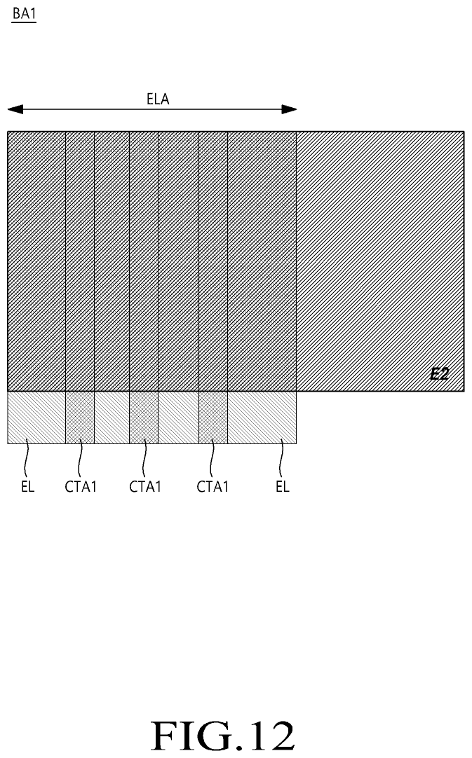

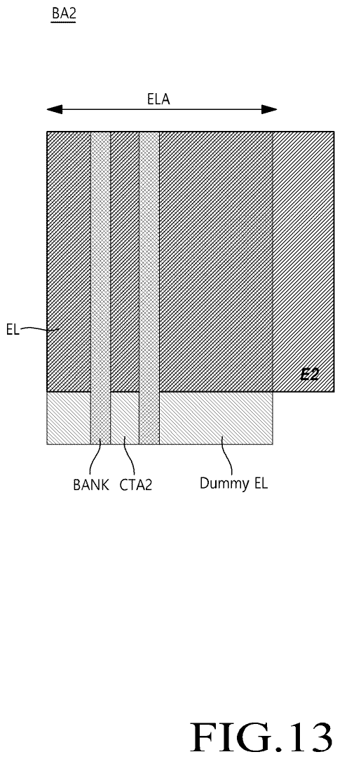

FIG. 12 is an example plan view of a first contact area formed in the first bezel area BA1 in the display panel 110 according to aspects of the present disclosure. FIG. 13 is an example plan view of a second contact area formed in the second bezel area BA2 in the display panel 110 according to aspects of the present disclosure.

Referring to FIG. 12, in one or more example embodiments, in the first bezel area BA1 of the display panel 110, a first contact area CTA1 in which a first electrode E1 and a second electrode E2 electrically contact each other in an emission layer area ELA in which an emission layer EL is disposed, can be formed in multiple numbers (e.g., in a plurality of lines). For example, a plurality of first contact areas CTA1, in each of which a first electrode E1 and a second electrode E2 electrically contact each other in an emission layer area ELA in which an emission layer EL is disposed, can be disposed.

In the first bezel area BA1, the first electrode E1 can extend to a dam area. Therefore, the first electrode E1 located in the first bezel area BA can have an area greater than the first electrode E1 located in the second bezel area BA2.

Since a base voltage line for delivering a base voltage to the second electrode E2 can be disposed in the first bezel area BA1, it can be desirable to increase the area of the first contact area CTA1. Taking account of this, in the first bezel area BA1, the first contact area CTA1 can be formed in a plurality of lines in the emission layer area ELA where the emission layer EL is disposed, in order to improve the electrical connection.

According to these configurations, when the first contact area CTA1 is formed in a plurality of lines in the first bezel area BA1, an area where the first electrode E1 and the second electrode E2 electrically contact each other can increase, and thereby, a voltage drop by the second electrode E2 can be reduced.

In one or more aspects, referring to FIG. 13, in the second bezel area BA2, a second contact area CTA2 where the first electrode E1 and the second electrode E2 electrically contact each other in the emission layer area ELA where the emission layer EL is disposed can be formed in a single line.

An area of the second contact area CTA2 disposed in the second bezel area BA2 can be less than an area of the first contact area CTA1 disposed in the first bezel area BA1.

Since a base voltage line for delivering a base voltage to the second electrode E2 is not disposed in the second bezel area BA2, the area of the second contact area CTA2 where the first electrode E1 and the second electrode E2 electrically contact each other can be formed to have a relatively small width, or the second contact area CTA2 may not be formed.

FIG. 13 illustrates an example where the second contact area CTA2 is formed in a single line in the second bezel area BA2.

In one or more aspects, a dummy emission layer (Dummy EL) for forming a dummy subpixel can be disposed in the second bezel area BA2. In this configuration, the emission layer EL and the dummy emission layer (dummy EL) of the second bezel area BA2 can be separated by the second contact area CTA2.

In one or more aspects, in the display panel 110, an electrical contact of the first electrode E1 and the second electrode E2 at a position overlapping with an emission layer in the bezel area BA can be formed in various shapes.

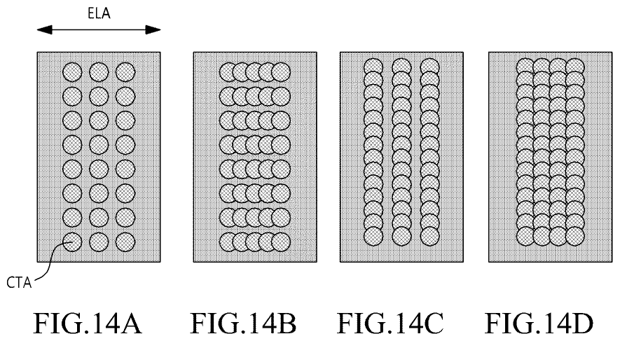

FIGS. 14A-14D illustrates example shapes of contact areas at which a first electrode E1 and a second electrode E2 electrically contact each other at a location overlapping with an emission layer EL in the bezel area BA in the display panel 110 according to aspects of the present disclosure.

Referring to FIGS. 14A-14D, in one or more example embodiments, in the display panel 110, a contact area CTA where the first electrode E1 and the second electrode E2 electrically contact each other can have a small circular dot shape.

When a high-frequency signal such as a laser is irradiated on an emission layer EL formed in the bezel area BA at a constant level, the emission layer EL can be cut off in a dot shape, and thereafter, the second electrode E2 can be formed thereon. According to this process, a dot-shaped contact area CTA can be formed.

In this configuration, as shown in FIG. 14A, a dot-shaped contact area CTA in which the first electrode E1 and the second electrode E2 electrically contact each other can be formed in multiple numbers in an emission layer area ELA where an emission layer EL is disposed. For example, a plurality of dot-shaped contact areas CTA, in each of which the first electrode E1 and the second electrode E2 electrically contact each other, can be formed in an emission layer area ELA where an emission layer EL is disposed.

In one or more aspects, the multiple dot-shaped contact areas CTA can be spaced apart from each other or can overlap with each other in one or more portions of each, or one or more, of the multiple dot-shaped contact areas CTA depending on a location where a high-frequency signal is emitted. For example, as shown in FIG. 14A, holes cut through the emission layer EL for connecting the first electrode E1 and the second electrode E2 with each other can be formed in a grid arrangement, but embodiments are not limited thereto.

As shown in FIG. 14B, a plurality of dot-shaped contact areas CTA can overlap with each other in the horizontal direction (e.g., thus cutting horizontal lines through the emission layer EL), and as shown in FIG. 14C, a plurality of dot-shaped contact areas CTA can overlap with each other in the vertical direction (e.g., cutting vertical lines). In one or more aspects, as shown in FIG. 14D, a plurality of dot-shaped contact areas CTA can overlap with each other in both the horizontal and vertical directions (e.g., cutting wide or thick line, such as having a rectangular shape).

In one or more aspects, in the display panel 110, a contact area CTA can be formed in the first bezel area BA1, or be formed in both the first bezel area BA1 and the second bezel area BA2.

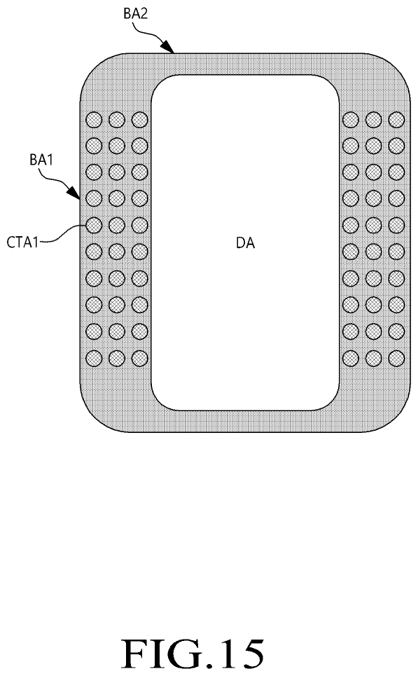

FIG. 15 illustrates an example first contact area formed in the first bezel area BA1 in the display panel 110 according to aspects of the present disclosure.

Referring to FIG. 15, in one or more example embodiments, the display panel 110 can have a first contact area CTA1 formed in the first bezel area BA1.

The first bezel area BA1 can be an area where a base voltage line to which a base voltage is applied is disposed, and can correspond to a portion of the bezel area BA on the left and right of the display panel 110.

In one or more aspects, the second bezel area BA2 can be an area where a base voltage line is not disposed, and can correspond to a portion of the bezel area BA on and underneath of the display panel 110 in a plan view.

In one or more aspects, a first contact area CTA1 in which a first electrode E1 and a second electrode E2 electrically contact each other at a position overlapping with an emission layer EL in the first bezel area BA1, can be formed in a plurality of dot shapes. For example, a plurality of dot-shaped first contact areas CTA1 in each of which a first electrode E1 and a second electrode E2 electrically contact each other at a position overlapping an emission layer EL in the first bezel area BA1, can be formed.

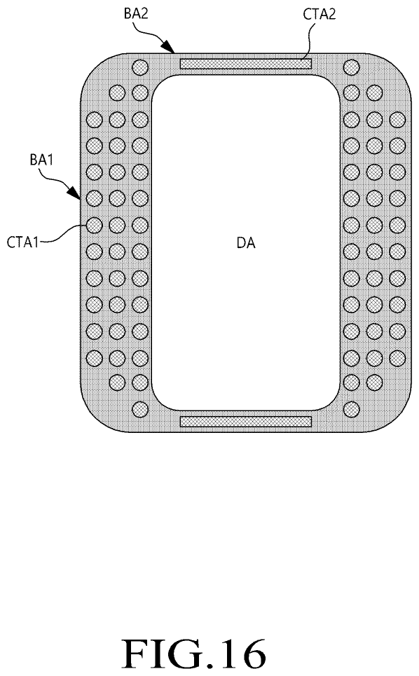

FIG. 16 illustrates example contact areas differently formed in the first bezel area BA1 and the second bezel area BA2 in the display panel 110 according to aspects of the present disclosure.

Referring to FIG. 16, in one or more example embodiments, the display panel 110 can have a first contact area CTA1 formed in the first bezel area BA1 and a second contact area CTA2 formed in the second bezel area BA2 with different structures.

A first contact area CTA1 in which a first electrode E1 and a second electrode E2 electrically contact each other at a position overlapping with an emission layer EL in the first bezel area BA1, can be formed in a plurality of dot shapes. For example, a plurality of dot-shaped first contact areas CTA1, in each of which a first electrode E1 and a second electrode E2 electrically contact each other at a position overlapping with an emission layer EL in the first bezel area BA1, can be formed. In this configuration, the plurality of dot-shaped first contact areas CTA1 can be disposed along the shape of the first bezel area BA1. Therefore, the first contact areas CTA1 can be disposed in a large area in the middle portion of the first bezel area BA1, and the area where the first contact areas CTA1 are disposed can decrease toward the top and bottom of the first bezel area BA1 (e.g., a row of 3 dot-shaped holes, then a row of 2 dot-shaped holes, then a row of 1 dot-shaped hole, etc.).

In one or more aspects, a plurality of second contact areas CTAs, in each of which a first electrode E1 and a second electrode E2 electrically contact each other at a position overlapping with an emission layer EL in the second bezel area BA2, can be formed in a straight line shape (e.g., a hole cut through the emission layer EL having a horizontal bar shape).

As discussed above, as the display device 100 includes a structure where a first electrode E1, which is an anode electrode, and a second electrode E2, which is a cathode electrode, electrically contact each other at a position overlapping with an emission layer EL in the bezel area BA, the display device 100 can provide advantages of reducing the electrical resistance of the second electrode E2 and minimizing a voltage drop caused by the second electrode E2.

Further, as the display device 100 includes a structure where one or more contact areas CTA in which the first electrode E1 and the second electrode E2 are electrically connected to each other are formed in different shapes depending on a portion of the bezel area BA by considering the arrangement of a base voltage line for delivering a base voltage to the second electrode E2, the display device 100 can provide advantages of ensuring a deposition margin of the bezel area BA and implementing a narrow bezel.

The examples, aspects, and embodiments described herein will be briefly described as follows.

According to the one or more example embodiments described herein, a display panel can be provided that includes a display area in which light emitted from a light emitting element including a first electrode, an emission layer, and a second electrode is presented, and a bezel area located outside of the display area and including an auxiliary electrode electrically contacting the second electrode at a contact area overlapping with the emission layer.

In one or more aspects, the emission layer can extend from the display area to the bezel area.

In one or more aspects, the contact area can be an area where the portion of the emission layer is cut off or burned away by a high-frequency signal in the bezel area.

In one or more aspects, the first electrode can be an anode electrode, and the second electrode can be a cathode electrode. In one or more aspects, the auxiliary electrode can be separated from the first electrode and can include the same material as the first electrode.

In one or more aspects, the second electrode can cover the emission layer in the bezel area.

In one or more aspects, the bezel area can include a disconnection area where the second electrode and the auxiliary electrode are not electrically connected.

In one or more aspects, the bezel area can include a first bezel area in which a base voltage line for delivering a base voltage to the second electrode is disposed, and a second bezel area in which the base voltage line is not disposed. In one or more aspects, the contact area can include a first contact area disposed in the first bezel area and a second contact area disposed in the second bezel area, and the first and second contact areas can have different shapes.

In one or more aspects, the first contact area can have a width less than an open area of a bank on the emission layer.

In one or more aspects, the first contact area can be disposed in multiple numbers in the open area of the bank.

In one or more aspects, the first contact area can be disposed in a straight line shape.

In one or more aspects, the first contact area can be disposed in a plurality of dot shapes.

In one or more aspects, the first contact area can be disposed in multiple numbers, and a corresponding portion of one or more of the multiple first contact areas can overlap with a corresponding portion of one or more of the remaining one or more first contact areas.

In one or more aspects, the first contact area can be disposed along a shape of the first bezel area.

In one or more aspects, the second contact area can be disposed in a single straight line shape.

In one or more aspects, the second contact area can include a disconnection area in which the second electrode and the auxiliary electrode are not electrically connected.

In one or more aspects, the bezel area can include a dam area in which one or more dams are disposed to prevent or reduce an organic encapsulation layer in a liquid form located in the display area from overflowing, and the auxiliary electrode can be disposed up to the dam area. In one or more aspects, the contact area can be disposed between the display area and the dam area.

According to the one or more example embodiments described herein, a display device can be provided that includes a display panel including a display area in which light emitted from a light emitting element including a first electrode, an emission layer, and a second electrode is presented, and a bezel area located outside of the display area and including an auxiliary electrode electrically contacting the second electrode at a contact area overlapping with the emission layer, and a driving circuit configured to drive the display panel.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display panel comprising:
a display area including a light emitting element having a first electrode, an emission layer, and a second electrode; and
a bezel area located outside of the display area,
wherein the bezel area includes an auxiliary electrode and a contact area, and
wherein the second electrode is in electrical contact with the auxiliary electrode at the contact area, and the contact area corresponds to at least one hole in the emission layer.

2. The display panel of claim 1, wherein the emission layer extends from the display area to the bezel area.

3. The display panel of claim 1, wherein the at least one hole in the emission layer in the contact area is formed by a high-frequency signal or a laser.

4. The display panel of claim 1, wherein the first electrode is an anode electrode, and the second electrode is a cathode electrode, and
wherein the auxiliary electrode is separated from the first electrode and includes a same material as the first electrode.

5. The display panel of claim 4, wherein the second electrode covers the emission layer in the bezel area.

6. The display panel of claim 1, wherein the bezel area includes a disconnection area, and
wherein the second electrode and the auxiliary electrode are electrically isolated from each other in the disconnection area.

7. The display panel of claim 1, wherein the bezel area includes a first bezel area including a base voltage line configured to supply a base voltage to the second electrode, and a second bezel area that does not include the base voltage line,
wherein the contact area includes a first contact area in the first bezel area and a second contact area in the second bezel area, and
wherein a shape of the first contact area in the first bezel area is different than a shape of the second contact area in the second bezel area.

8. The display panel of claim 7, wherein a width of the first contact area is less than a width of an open area of a bank on the emission layer.

9. The display panel of claim 8, wherein the first contact area includes a plurality of first contact areas in the open area of the bank.

10. The display panel of claim 8, wherein the first contact area has a straight line shape or a rectangular bar shape.

11. The display panel of claim 7, wherein the first contact area has a plurality of dot shapes.

12. The display panel of claim 11, wherein the first contact area includes a plurality of first contact areas, and
wherein at least two adjacent first contact areas among the plurality of first contact areas overlap with each other.

13. The display panel of claim 7, wherein the first contact area extends along a shape of the first bezel area.

14. The display panel of claim 7, wherein the second contact area has a single straight line shape or a rectangular bar shape.

15. The display panel of claim 7, wherein the second contact area includes a disconnection area, and
wherein the second electrode and the auxiliary electrode are electrically isolated from each other in the disconnection area.

16. The display panel of claim 7, wherein the second bezel area further includes a dummy emission layer separated from the emission layer by the second contact area.

17. The display panel of claim 1, wherein the bezel area includes a dam area,
wherein the dam area includes one or more dams configured to prevent an organic encapsulation layer in the display area from overflowing,
wherein the auxiliary electrode extends to the dam area, and
wherein the contact area is between the display area and the dam area.

18. A display device comprising:
a display panel including:
a display area including a light emitting element having a first electrode, an emission layer, and a second electrode, and
a bezel area located outside of the display area; and
a driving circuit configured to drive the display panel,
wherein the bezel area includes an auxiliary electrode and a contact area, and
wherein the second electrode is in electrical contact with the auxiliary electrode at the contact area, and the contact area corresponds to at least one hole in the emission layer.

19. A display device comprising:
a plurality of subpixels disposed in a display area of a substrate;
a first electrode layer disposed across the display area;
an emission layer disposed on the first electrode layer and extending into a bezel area of the substrate, the bezel area being located outside of the display area;
a second electrode layer disposed on the emission layer and extending into the bezel area;
an auxiliary electrode disposed in the bezel area, the auxiliary electrode being separated from the first electrode layer in the display area; and
at least one hole extending through the emission layer in the bezel area,
wherein the auxiliary electrode includes a same material as the first electrode layer, and
wherein the second electrode layer contacts the auxiliary electrode in the at least one hole in the bezel area.

20. The display device of claim 19, wherein the at least one hole extending through the emission layer in the bezel area includes a plurality of holes arranged in a grid pattern, or
wherein the at least one hole extending through the emission layer in the bezel area has a bar shape or a shape of a plurality of overlapping dots.
